(19) United States
(12) Patent Application Publication
(10) Pub. No.: US 2011/0212256 A1
(43) Pub. Date: Sep. 1, 2011

(54) DEPOSITION RATE CONTROL

(75) Inventors: Markus E. Beck, Scotts Valley, CA (US); Ming L. Yu, Fremont, CA (US); Erel Milshtein, Cupertino, CA (US); Ashish Bodke, San Jose, CA (US); Ulrich A. Bonne, Sunnyvale, CA (US); Raffi Garabedian, Los Altos, CA (US)

(73) Assignee: First Solar, Inc., Perrysburg, OH (US)

(21) Appl. No.: 13/025,431

(22) Filed: Feb. 11, 2011

Related U.S. Application Data
(60) Provisional application No. 61/304,058, filed on Feb. 12, 2010.

(51) Int. Cl. C23C 16/52; C23C 16/455

(52) U.S. Cl. 427/10; 427/8; 427/9; 118/688; 118/667; 118/665

(57) ABSTRACT

An vapor deposition control system includes a multi-level control scheme.

### CLAIM OF PRIORITY

This application claims priority to U.S. Provisional Patent Application No. 61/304,058, filed on Feb. 12, 2010, which is incorporated by reference in its entirety.

### TECHNICAL FIELD

This invention relates to a material deposition process, which can include a deposition rate control system.

### BACKGROUND

Evaporation is a common method of thin film deposition. The source material can be evaporated under reduced pressure, such as in a vacuum. The vacuum allows vapor flux to travel directly to the target object, where it condenses back to a solid state. Evaporation is used in microfabrication, and to make macro-scale products such as solar cell or metalized plastic film. Controlling the deposition rates from evaporation sources can prove to be difficult, in particular in an ambient environment of background elements or for wide rate ranges.

### DESCRIPTION OF DRAWINGS

FIG. 1 is a schematic showing the one-stage multilevel thermal evaporation deposition control system.

FIG. 2 illustrates a setup of optical elements of a deposition control system.

FIG. 3 illustrates a receiving end setup of optical elements of the flux rate monitor.

FIG. 4 is a diagram of an exemplary photodiode output waveform.

FIG. 5 is a schematic showing the thermal evaporation deposition process of the CIGS layer.

FIG. 6 illustrates a three-stage multilevel control scheme.

FIG. 7 illustrates a three-stage multilevel control scheme.

FIG. 8 illustrates a configuration of a near infrared reflectometry sensor with an in-situ configuration for in-line deposition process.

FIG. 9 illustrates a configuration of an X-ray fluorescence sensor with an in-situ configuration for in-line deposition process.

### DETAILED DESCRIPTION

In evaporation deposition, a metal source can be heated by certain methods, such as passing a current through a container or by focusing an electron beam on the metal's surface. As metal evaporates, it forms a vapor flux that condenses on the cooler surface of the target object (e.g. substrates) to form a thin film. Evaporation is widely used in microfabrication, and to make macro-scale products such as solar cell or metalized plastic film. Controlling the deposition rates from evaporation sources can prove to be difficult, in particular in an ambient environment of background elements or compounds or for wide rate ranges. An evaporation rate control system with multi-level control approach is developed for thin film deposition process.

If various elements or compounds are coevaporated, species sensitive information and compositional control are both desirable. Various rate monitor technologies exist: some are species sensitive, while others are not. Not all of these sensors are equally capable to operate under a wide range of ambient conditions (atmosphere, temperature). Furthermore, in-situ measurement result of the flux rate is most likely not equal to the deposition rate on the substrate. This can result from the material being deposited having a sticking coefficient dictating that less than all the atoms of the material that impinge on a substrate will be deposited. While for well known conditions it may be possible to establish correlation factors of flux rate versus deposition rate, fluctuations in the process conditions (intentional or unintentional) cannot be detected, nor compensated for. Thus, design principles would necessitate solutions of inherently stable sources, but this is not always possible or desirable. At the same time, a control scheme needs to be capable of detecting and reacting to fluctuations in the process condition to compensate for variations in the flux to deposition rate relationship. The evaporation rate control system disclosed herein addresses this problem via a control loop approach.

In one aspect, a method of controlling a vapor deposition rate and composition includes measuring a vapor flux rate of a vapor being fed from a vapor source and deposited and calculating a deposition rate based on the measured vapor flux rate. A correlation function between flux rate and the deposition rate can be used to calculate the deposition rate. The method can include controlling the deposition rate by a feedback control loop based on the deposition rate.

The method can include the steps of measuring a vapor source temperature of the vapor source and controlling the deposition rate by a first check control loop. The first check control loop can include a correlation function between vapor source temperature and deposition rate which can be used to verify the calculated deposition rate by using the measured vapor source temperature. The method can include the steps of measuring a vapor source power of the vapor source and controlling the deposition rate by a second check control loop. The second check control loop can include a correlation function between vapor source power and deposition rate to verify the calculated deposition rate by using the measured vapor source power. The method can include the steps of measuring a vapor source temperature of the vapor source and controlling the vapor flux rate by a first check control loop. The first check control loop can include a correlation function between flux rate and vapor source temperature which can be used to verify the measured vapor flux rate by using the measured vapor source temperature.

The method can include establishing a target deposition layer thickness of the deposited vapor. The method can include setting the vapor flux rate based on the target deposition layer thickness. The method can include measuring the deposited film thickness during deposition. The method can include comparing the measured deposited film thickness to the target deposition layer thickness and controlling the deposition rate by a feedback control loop based on the measured deposition film thickness. The deposition film thickness can be measured using a near infrared reflectometer. The deposition film thickness can be measured using an X-ray fluorescence sensor. The deposition film thickness can be measured using an ellipsometer. The deposition film thickness can be measured using a light scattering sensor. The deposition film thickness can be measured using an optical transmission sensor. The deposition film thickness can be measured using an in-situ instrument to monitor the deposition process in real time.

The method can include the steps of adjusting the vapor flux rate and iterating until the target deposition layer thickness is present. Measuring the deposition film thickness can include timing the deposition film thickness measurement to occur after the step of measuring the flux rate. Measuring the deposition film thickness can include timing the deposition film thickness measurement to occur after vapor has been deposited. Measuring the vapor flux can include using an atomic absorption spectrometer. Measuring the vapor flux can include using an electron impact emission spectrometer. Measuring the vapor flux can include using an ion gauge. Measuring the vapor flux can include using a configuration enabling the monitor to measure the position sensitive flux rate.

A vapor deposition rate control system can include a vapor flux monitor capable of measuring a vapor flux rate of a vapor being deposited, a vapor flux control module capable of reading the flux monitor and controlling the vapor flux rate by adjusting a vapor source feed rate from a vapor source, and a feedback control loop. The feedback control loop can be based on a correlation function between the flux rate and a deposition rate of the vapor being deposited, to correlate the flux rate to the deposition rate and control the deposition rate by the control module.

The vapor deposition control system can include a vapor source temperature sensor capable of measuring a vapor source temperature of the vapor source, and a first check control loop. The first check control loop can include a correlation function between vapor source temperature and deposition rate to compare the deposition rate correlated to the vapor source temperature with the deposition rate correlated to the measured flux rate. The system can include a vapor source power sensor capable of measuring a vapor source power of the vapor source, and a second check control loop. The second check control loop can include a correlation function between vapor source power and deposition rate to compare the deposition rate correlated to the vapor source power with the deposition rate correlated to the measured flux rate. The vapor deposition control system can include a vapor source temperature sensor capable of measuring a vapor source temperature of the vapor source, and a first check control loop. The first check control loop can include a correlation function between vapor source temperature and flux rate to compare the flux rate correlated to the vapor source temperature with the measured flux rate.

The vapor deposition rate control system can include a data storage apparatus storing a target deposition layer thickness of a deposited vapor. The data storage apparatus can include a self-teaching algorithm to allow selection of the vapor flux rate as a function of the target deposition layer thickness. The system can include film thickness monitor capable of measuring the thickness of a deposited vapor. The film thickness monitor can include an in-situ configuration when measuring the thickness of a deposited vapor. The film thickness monitor can include a near infrared reflectometer. The film thickness monitor can include an X-ray fluorescence sensor. The film thickness monitor can include an ellipsometer. The film thickness monitor can include a light scattering sensor. The film thickness monitor can include an optical transmission sensor. The film thickness monitor can monitor the deposition process in real time.

The vapor deposition rate control system can include a film thickness control module capable of adjusting the vapor flux rate and iterating until the target deposition layer thickness is present. The film thickness monitor can measure deposition layer thickness after the flux rate is measured. The vapor flux monitor can include an atomic absorption spectrometer. The vapor flux monitor can include an electron impact emission spectrometer. The vapor flux monitor can include an ion gauge. The vapor flux monitor can be configured to enable the monitor to measure the position sensitive flux rate.

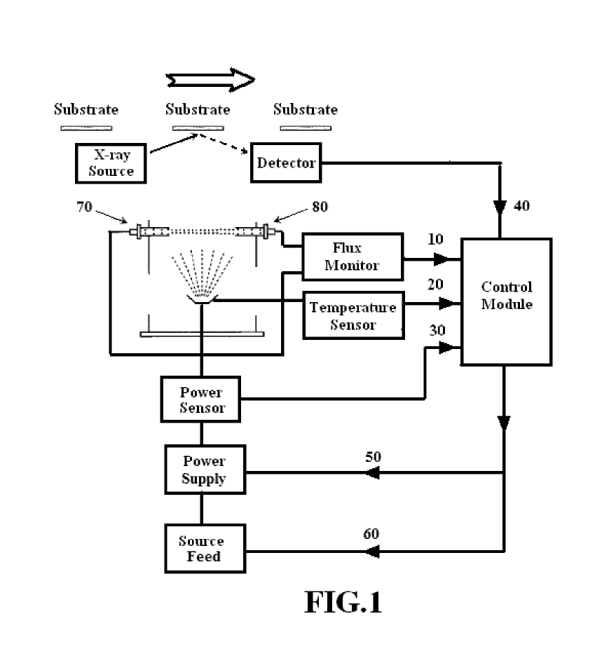

Referring to FIG. 1, in certain embodiments, a one-stage multilevel thermal vapor deposition control system can include a control module. The control system can include a vapor flux monitor, a vapor source temperature sensor, and a vapor source power sensor as first level sensors. The vapor flux monitor can include optical elements 70, 80 used to measure the vapor flux rate of the vapor being deposited. The control system can use correlation functions of flux rate versus deposition rate to engage a feedback control loop via flux monitor's measurement 10. Because the material being deposited can have a sticking coefficient of less than 1.00 (in which case, for example, less than all atoms impinging on the deposition surface are deposited), a measured flux rate can be multiplied by the sticking coefficient (among other suitable calculations) to determine a deposition rate.

The evaporation rate control system can include one or more check control loops to evaluate and/or refine the deposition rate determined based on the measured flux rate, and the methodology for calculating the deposition rate. For example, the evaporation rate control system can use the vapor source temperature sensor as part of a first check control loop, wherein a correlation function between the vapor source temperature 20 and the deposition rate can be used to verify the deposition rate calculated based on the measured flux rate. The evaporation rate control system can include additional or alternate check control loops. For example, the evaporation rate control system can use the vapor source power sensor as part of a second check control loop, wherein a correlation function between deposition rate and vapor source power 30 can be used to verify the deposition rate calculated based on the measured vapor flux rate. The evaporation rate control system can include a check control loop which correlates flux rate and vapor source temperature to verify the measured vapor flux rate by using the vapor source temperature 20 measured by the vapor source temperature sensor.

In some embodiments, a second level film thickness sensor can be applied in-situ during the vapor deposition to send deposited film thickness measurement 40 to the control module. When the film thickness supervisory sensor detects a discrepancy to a desired target deposition layer thickness, it can adjust the vapor flux rate and iterate until the target deposition layer thickness is achieved. The vapor deposition control system can use any suitable tool, instrument, or method or combination or tools, instruments, or methods to measure the film thickness of the deposited vapor layer. For example, an X-ray fluorescence sensor (XRF) can be used to measure the film thickness of the deposited layer. X-ray fluorescence sensor (XRF) can include an energy dispersive spectrometer (EDS). The energy dispersive spectrometer can detect the emission of characteristic “secondary” (or fluorescent) X-rays from a material that has been excited by bombarding with high-energy X-rays (or gamma rays). By analyzing the emission, the energy dispersive spectrometer can also provide compositional information of the deposited layer on the substrates. A near infrared reflectometer (NIR) can be used to measure film thickness and can be included in the film thickness monitor.

The vapor deposition control system can use the control module to adjust vapor source power 50 or continuous feed thermal evaporation sources 60. In some embodiments, the integrated signals from the sensors allow direct access to the material consumption/mass loss of the source. Therefore, it can be used to control the feedstock replenishment mechanism controlling the source to a fixed fill level. It can also be used to control the vapor source power to a fixed evaporation level. In some embodiments, the vapor deposition control system can control the deposition rate of an in-line, multi-stage deposition system capable of continuous processing of moving substrates. Several evaporation sources can be used in an in-line configuration in the system.

The vapor flux rate monitor can include an atomic absorption spectrometer or any other suitable sensors (e.g. electron impact emission spectrometer or ion gauges). When an excited atom de-excites, it emits a photon of characteristic wavelength. Atomic absorption (AA) is the reverse of this process. If a beam of light at the characteristic wavelength passes through a cloud of atoms with uniform density across the light beam diameter, photons will be absorbed by the atoms. The amount of absorption will depend on the number of atoms in the light path.

For example, let

Iᵢₙ=incident light intensity

Iₒᵤₜ=transmitted light intensity

N=number of atoms the beam interacts.

Beer's law states that

Iₒᵤₜ=Iᵢₙexp(−N/α)

α is a constant that is related to the cross-section of optical absorption.

N=α ln(Iᵢₙ/Iₒᵤₜ).

The ratio Iₒᵤₜ/Iᵢₙ is directly related N. Therefore AA can be used as a monitor of metal flux. Note that

dIₒᵤₜ/dN=−(Iₒᵤₜ/α).

AA is most sensitive when Iₒᵤₜ is large, or when N is small. The major characteristic absorption lines of Cu, In, and Ga are shown below:

Copper 324.75(s)/327.40/217.90 nm

Gallium 287.4/294.36(s)/403.3 nm

Indium 303.94(s)/325.61 nm

‘s’ means the strongest. Therefore, the working wavelength of the light source can be in the 280-330 nm range in the UV.

In some embodiments, the light source for AA can include the Hollow Cathode Lamp (HCL) where an Ar or Ne plasma excites the atoms of interest to emit the characteristic lines. The light source for AA can include a tunable laser. There are diode lasers in the wavelengths of interest. The emission from HCL can include a background of many other emission lines. A bandpass filter either at the source or at the detector can be used to filter the unwanted emission lines. The intensity ratio Iₒᵤₜ/Iᵢₙ is needed for the measurement. Iᵢₙ can be measured by shuttering off the metal vapor. Another detector can be used to monitor the HCL output. Therefore, corrections can be made to the light intensity if necessary. The transmission of the optical system may change due to metal deposition on the optical elements. If the metal vapor can be shuttered off to measure Iᵢₙ, it will be equivalent to an intensity change of the light source and be used as above. A “white” light source, i.e., one that is not absorbed or scattered by the metal vapor can also be used to monitor the change in the transmission.

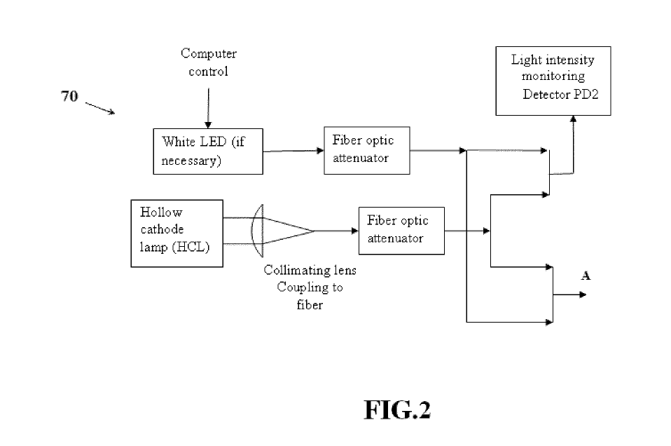

Referring to FIG. 2, as a sending end setup of optical elements of the system (70 in FIG. 1 and FIG. 2), a hollow cathode lamp can remain on during the experiment to maintain stability. The broad (about 1″-1.5″) emission from the HCL is coupled through a collimating lens to the optical fiber. The light is split, part to the light intensity monitoring detector PD2 (if necessary), and part for flux measurement (A). A fiber optic attenuator can be used to adjust the light intensity. The white LED can be turned on and off by the computer. It is also split between the light intensity monitoring detector PD2 and for measurement (A). A mechanical shutter can be included to eliminate the necessity of a white light path.

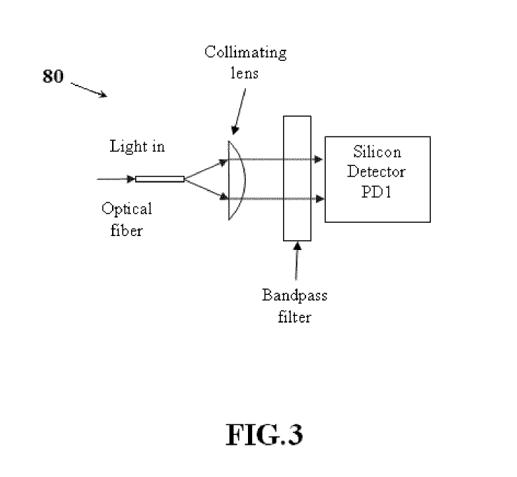

With shuttering capability, both Iᵢₙ and Iₒᵤₜ can be obtained with a single detector. As mentioned above, the HCL has a background besides the main emission line. Referring to FIG. 3 showing a receiving end setup of optical elements of the flux rate monitor (80 in FIG. 1 and FIG. 3), a UV bandpass filter can be positioned in front of the detector. The detector can be a Si photodiode. The light coming out from vapor flux will be transported through the evaporation chamber wall by optical fiber vacuum feedthrough. The output will be collimated by a small collimating lens onto a silicon photodiode PD1 outside the chamber.

In one embodiment, a procedure for metal flux measurement includes the following steps:
1. Set HCL optical attenuator to zero transmission. Read the background signal I_{back}. I_{back} is from stray light and the dark current of the detector.
2. With shutter on (no metal flux), adjust the fiber optic attenuator so that the silicon photodiode output is within the linear range of the detector. The signal Iₛₕᵤₜ=Iᵢₙ+I_{back}.
3. Open the shutter (metal flux on). The signal is Iₒₚₑₙ=Iₒᵤₜ+I_{back}.

From Beer's law:

N=α ln [(Iₛₕᵤₜ−I_{back})/(Iₒₚₑₙ−I_{back})].

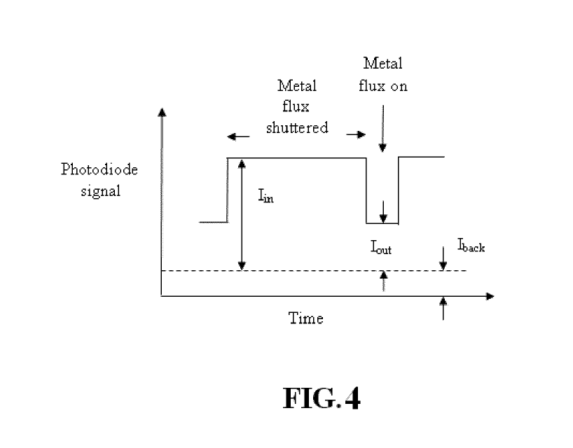

N can not be obtained directly without knowing the proportionality constant α. This is not necessary for the purpose of flux control. The value α can be measured, for example, by measuring the thickness of the deposited film. Referring to FIG. 4, an exemplary photodiode output waveform is shown. As shown in FIG. 3, the photodiode output waveform can be idealistic square wave function in case of shuttered flux, for example, in a system including a fast shutter to shutter the flux resulting substantially in only either an on state or an off state. In some embodiments, a slower shutter can be used, resulting in a sloped output waveform.

In the case when the metal flux can not be shuttered, the light intensity monitoring detector and the “white” LED can be included in the flux rate monitor to calibrate out any change in the transmission in the AA optical path, for example, due to metal deposition on the optical elements. The light intensity monitoring detector can be called PD2. The AA signal photodiode can be called PD1. The calibration is needed between PD1 and PD2 for both the AA sensing light and the white LED, assuming that the background signals from the two PDs are always subtracted already.

In certain circumstances, procedure for calibration can be:
1. Metal source off
2. Turn on HCL until stable
3. With white LED off or LED fiber attenuator set to zero output, set the HCL light level to a convenient value for measurement using the HCL fiber attenuator
4. Read PD1 and PD2 outputs
5. Initial calibration factor k_{HCLi}=PD1 output/PD2 output
6. Take out the UV bandpass filters for the photodiode detectors
7. With HCL fiber attenuator set to zero output, set the LED light level to a convenient value for measurement using the LED fiber attenuator
8. Read PD1 And PD2 outputs
9. Initial calibration factor k_{LEDi}=PD1 output/PD2 output

In some embodiments, during metal flux measurement, the HCL can be kept on to maintain its stability. Therefore, PD1 can always have an output I_{AA} as the AA signal. However, the transmission of the optics may change due to metal deposition on the optics elements. Therefore, the correction needs to be made. For this measurement, the white LED whose light may not be attenuated to any significant extent by the metal flux can be used. The procedure to make transmission correction can be:

1. Block off the HCL light

2. Take out the UV bandpass filters

3. LED on

4. Take reading:
a. PD1: I_{LED1}
b. PD2: I_{LED2}

5. Take the ratio k_{LED}=I_{LED1}/I_{LED2}

6. Transmission correction factor β=k_{LEDi}/k_{LED}

7. The transmission correction factor has to be applied to the AA signal.

8. Turn off LED

9. Unblock HCL

10. Replace UV bandpass filters

11. Take reading:
a. PD1: I_{AA}
b. PD2: I_{HCL}

Iₒᵤₜ=I_{AA}

Iᵢₙ=I_{HCL}*k_{HCLi}/β.

Therefore

$$\begin{matrix}N = α ln ( {I}_{i n} / {I}_{out} ) \\ = α ln ( {I}_{HCL} * {k}_{HCLi} / β {I}_{AA} ) \\ = α ln [ ( PD 2 signal / PD 1 signal ) * ( {k}_{HCLi} / β ) ]\end{matrix}$$

Here α has the same value as the α for the shuttered case.

The above-described control loop can only guarantee that the flux rate will be constant, but can be blind with respect to external condition changes that impact the deposition rate, such as sticking coefficient, background species, substrate temperature variations, or source power fluctuation. When various elements or compounds are coevaporated, such as CIGS film deposition, species sensitive information and compositional control are also desirable.

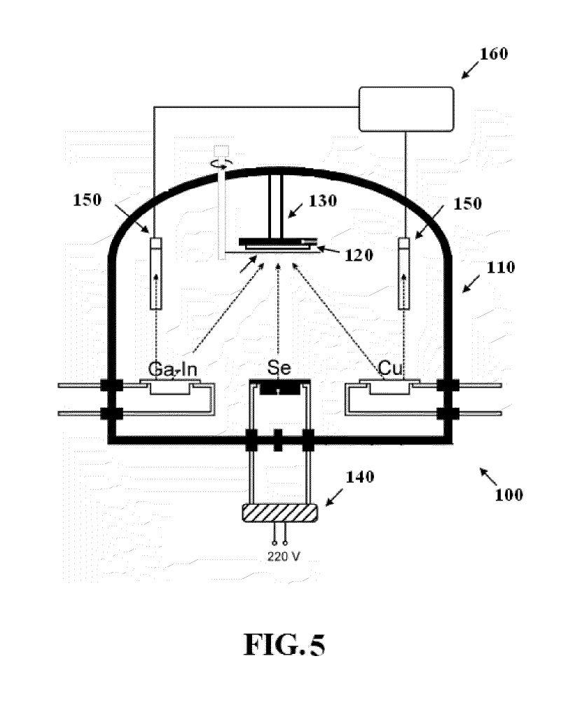

Photovoltaic devices using copper indium (di) selenide (CIS) and their alloys with gallium (CIGS) can be manufactured using a variety of techniques. Materials can be co-evaporated. Co-evaporation of CIGS thin film via two-stage and three-stage processes has been widely used. Referring to FIG. 5, CIGS film thermal evaporation system 100 can include chamber 110. Chamber 110 can be connected to a vacuum system which allows working at pressures of about 10⁻⁶ Torr. System 100 can include any suitable number of boats (e.g., three or four boats used to evaporate Se, In, (Ga), and Cu, respectively) and thickness monitor 160 with quartz crystal sensor 150, which was used for measuring the flux rate of the evaporated elements. System 100 can include programmable power source and related controller 140. Substrate 120 can be mounted on mounting fixture 130 or positioned in any other suitable manner. System 100 can further include any suitable substrate heating module if necessary. Mounting fixture 130 can be rotary and hold substrate 120 facing down. Evaporation processes can include a plurality of stages and species. In some embodiments, the CIGS deposition system can be an in-line, 3 stage deposition system capable of continuous processing of moving substrates. Several evaporation sources can be used in an in-line configuration in the system.

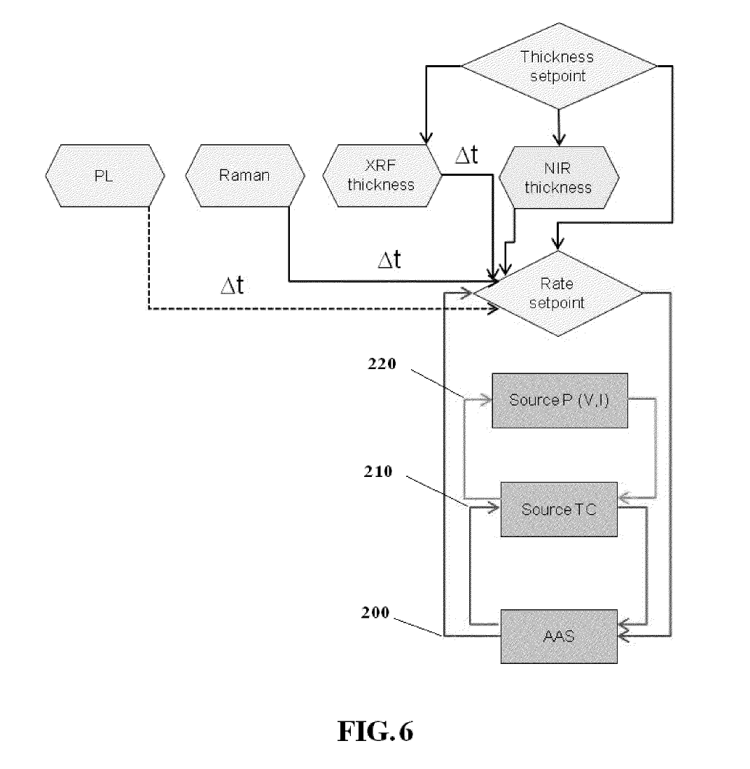

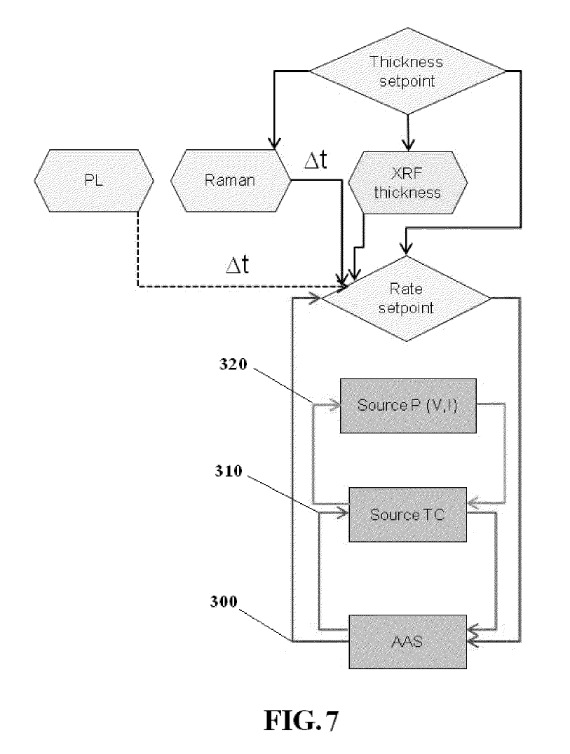

To monitor and control the rate and composition of deposition process (e.g. CIGS film deposition), the vapor deposition control system can use a multi-level control approach for thin film deposition process. The vapor deposition control system can include a desired target deposition layer thickness for the respective element or compound deposited. The target layer thickness for the respective element or compound can be sent to the control system. Referring to FIGS. 6 and 7, for a three-stage CIGS film deposition process, the control system can use previously established correlation functions of flux rate versus deposition rate to engage the feedback control loop (200 in FIG. 6, 300 in FIG. 7) via the flux monitor. At the same time, one or more check loops can be included to check that the calculated deposition rates based on the measured flux rates from the flux sensor agree with previously established source temperatures correlations as well as associated source power (e.g. current, voltage). For example, the evaporation rate control system can include a vapor source temperature sensor and a first check control loop (210 in FIG. 6, 310 in FIG. 7), wherein a correlation function between vapor source temperature and deposition rate can be used to verify the deposition rate calculated based on the measured vapor flux rate by using the vapor source temperature measured by the vapor source temperature sensor. The evaporation rate control system can also include a vapor source power sensor and a second check control loop (220 in FIG. 6, 320 in FIG. 7), wherein a correlation function between vapor source power and deposition rate can be used to verify the deposition rate calculated based on the measured vapor flux rate and/or the vapor source temperature by using the vapor source power (e.g. current, voltage) measured by the vapor source power sensor. The entire control loop can be based on self-teaching algorithms to allow fast selection of the initial target flux rate as a function of the desired layer thickness.

Referring to FIG. 6, a multilevel control scheme can use near infrared reflectometry (NIR) as a means to measure the optical film thickness of the deposited layer. The multilevel control scheme in FIG. 7 uses X-ray fluorescence sensor (XRF) as a means to measure the film thickness of the deposited layer. A film thickness monitor can use XRF or any other suitable means (e.g. ellipsometry, transmission, light scattering) to measure the thickness of a deposited vapor. X-ray fluorescence can measure film thickness and can further provide compositional information of the deposited layer, for compounds.

For faster feedback, the film thickness monitor can be applied in-situ during the growth phase and can be a second-level check on film thickness, after vapor flux rate. When the film thickness monitor detects a discrepancy to the desired target deposition layer thickness, it can adjust the vapor flux rate and iterate until the target deposition layer thickness is achieved. Time delays can be included in the second-level sensors shown in FIGS. 6 and 7. The timing of the second-level sensor can be after the vapor flux rate measurement. In an example of a three-stage CIGS film deposition, XRF feedback can be provided directly following stage 3 and NIR can be used in-situ in stages 1 and 2. Stage 3 can allow control of the process in such a way as to achieve the highest stage 1/stage 3 ratio and Cu-rich excursion while not requiring in-situ XRF for stage 1 and stage 2. This can significantly reducing cost and complexity. The timing can be designed in such a way that the system does not oscillate. In particular, the response time/time constant of the respective thermal evaporation source has to be taken into account. Moving outward from the innermost control loop one has to increase the time constants for each level of the next outer loop, as otherwise the system would oscillate.

Film thickness and substrate temperature can be measured at any suitable time and any suitable point deposition rate monitoring process. Film thickness and substrate temperature can be measured at the same time, or separately, depending on the circumstances. In some embodiments, the same equipment can be used to measure both film thickness and substrate temperature and in other embodiments, different equipment can be used. Non-contacting thermometers or pyrometers can detect and measure thermal radiation emitted from the substrate to determine the substrate's temperature in some embodiments. In other embodiments, thermopiles can be used to measure the substrate temperature.

Near infrared reflectometry can be used to measure either one or both of film thickness and substrate temperature. The near infrared reflectometer (NIR) can include an active spectral pyrometry device to extract deposited film thickness information by measuring and analyzing both the self-emission and reflection of a surface of the deposited film on the substrate. Where the film being measured has a thickness greater than the wavelength of the measuring light, a near infrared reflectometer positioned above the coated substrate (e.g. on the side with the deposited film) can be used to measure film thickness and temperature. Where the film being measured has a thickness less than the wavelength of the measuring light, a near infrared reflectometer placed above the coated substrate can be used to measure film thickness and a second instrument (such as a second near infrared reflectometer) can be positioned beneath the substrate and directed at the substrate to obtain temperature data. The near infrared reflectometer can be a suitable solution for the measurement of moving objects or any surfaces in harsh conditions that can not be reached or can not be touched.

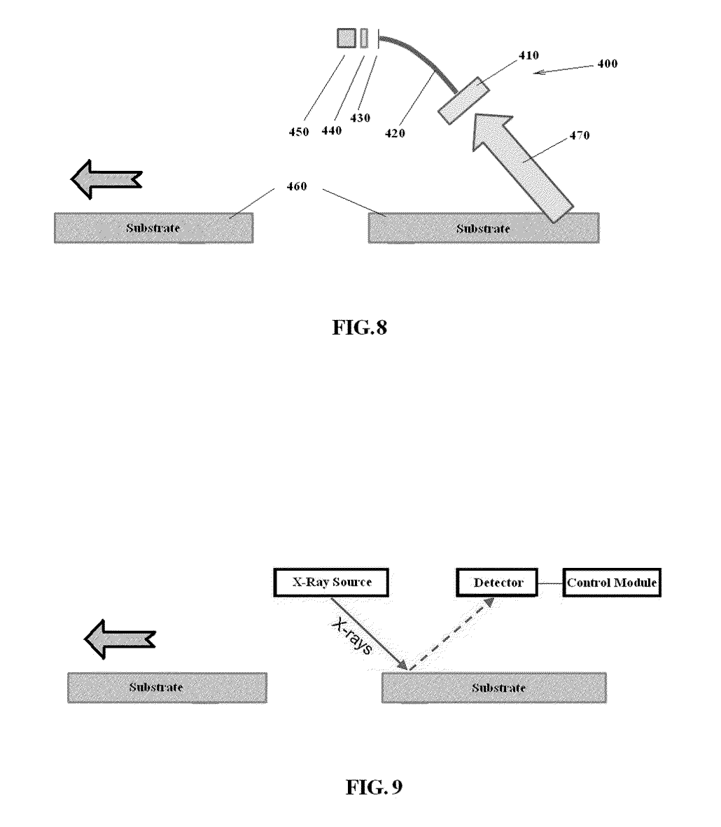

Referring to FIG. 8, near infrared reflectometer 400 can have an in-situ configuration for in-line deposition process. Near infrared reflectometer 400 can have lens 410 positioned to receive thermal radiation 470 from moving substrates 460. Optic fiber bundle 420 can be used to transmit thermal radiation 460. Mask 430 and filter 440 can be positioned in front of sensor 450. Sensor 450 can be used to measure thermal radiation 460. Sensor 450 can include an active spectral pyrometry device to extract deposited film thickness information.

X-ray fluorescence sensor (XRF) is widely used for elemental analysis and chemical analysis. X-ray fluorescence sensor (XRF) can include an energy dispersive spectrometer (EDS). Referring to FIG. 9, the energy dispersive spectrometer can detect the emission of characteristic “secondary” (or fluorescent) X-rays from a material that has been excited by bombarding with high-energy X-rays (or gamma rays). By analyze the emission, the energy dispersive spectrometer can provide compositional information of the deposited layer on the substrates.

In some embodiments, other aspects besides the integral film thickness may be of importance and additional sensors with supervisory functions can be introduced into the control architecture. The embodiments above illustrate the use of sensors that can help differentiate electronic or optical properties and if several evaporation sources are used in an in-line configuration can help establish non-integral compositional information. The vapor deposition control system can include a control module of continuous feed thermal evaporation sources. In some embodiments, the integrated signals from the sensors allow direct access to the material consumption/mass loss of the source. Therefore, it can be used to control the feedstock replenishment mechanism controlling the source to a fixed fill level. In other embodiments, for sources sensitive to small fluctuations in fill level, the rate monitor and source power loop can be used to control the continuous feeder.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A method of controlling a vapor deposition rate and composition comprising:
measuring a vapor flux rate of a vapor being fed from a vapor source and deposited;
calculating a deposition rate based on the measured vapor flux rate, wherein a correlation function between flux rate and the deposition rate is used to calculate the deposition rate; and
controlling the deposition rate by a feedback control loop based on the deposition rate.

2. The method of claim 1, further comprising:
measuring a vapor source temperature of the vapor source; and
controlling the deposition rate by a first check control loop, wherein the first check control loop comprises a correlation function between deposition rate and vapor source temperature to verify the calculated deposition rate by using the measured vapor source temperature.

3. The method of claim 2, further comprising:
measuring a vapor source power of the vapor source; and
controlling the deposition rate by a second check control loop, wherein the second check control loop comprises a correlation function between deposition rate and vapor source power to verify the calculated deposition rate by using the measured vapor source power.

4. The method of claim 1, further comprising:
measuring a vapor source temperature of the vapor source; and
controlling the deposition rate by a first check control loop, wherein the first check control loop comprises a correlation function between flux rate and vapor source temperature to verify the measured vapor flux rate by using the measured vapor source temperature.

5. The method of claim 1, further comprising establishing a target deposition layer thickness of the deposited vapor.

6. The method of claim 4, further comprising setting the vapor flux rate based on the target deposition layer thickness.

7. The method of claim 4, further comprising measuring the deposited film thickness during deposition.

8. The method of claim 6, further comprising comparing the measured deposited film thickness to the target deposition layer thickness and controlling the deposition rate by a feedback control loop based on the measured deposition film thickness.

9. The method of claim 6, wherein the deposition film thickness is measured using one or more of near infrared reflectometer, X-ray fluorescence sensor, ellipsometer, light scattering sensor, or optical transmission sensor.

10. The method of claim 6, wherein the deposition film thickness is measured using an in-situ instrument to monitor the deposition process in real time.

11. The method of claim 4, further comprising the steps of adjusting the vapor flux rate and iterating until the target deposition layer thickness is present.

12. The method of claim 6, wherein the step of measuring the deposition film thickness comprises timing the deposition film thickness measurement to occur after the step of measuring the flux rate.

13. The method of claim 6, wherein the step of measuring the deposition film thickness comprises timing the deposition film thickness measurement to occur after vapor has been deposited.

14. The method of claim 1, wherein the step of measuring the vapor flux comprises using an atomic absorption spectrometer, an electron impact emission spectrometer, an ion gauge, optionally in a configuration enabling the monitor to measure the position sensitive flux rate.

15. A vapor deposition rate control system comprising:
a vapor flux monitor capable of measuring a vapor flux rate of a vapor being deposited;
a vapor flux control module capable of reading the flux monitor and controlling the vapor flux rate by adjusting a vapor source feed rate from a vapor source; and
a feedback control loop based on a correlation function between the flux rate and a deposition rate of the vapor being deposited, to correlate the flux rate to the deposition rate and control the deposition rate by the control module.

16. The vapor deposition rate control system of claim 15, further comprising:
a vapor source temperature sensor capable of measuring a vapor source temperature of the vapor source; and
a first check control loop comprising a correlation function between deposition rate and vapor source temperature to compare the deposition rate correlated to the vapor source temperature with the deposition rate correlated to the measured flux rate.

17. The vapor deposition rate control system of claim 16, wherein the control system further comprises:
a vapor source power sensor capable of measuring a vapor source power of the vapor source; and
a second check control loop comprising a correlation function between flux rate and vapor source power to compare the deposition rate correlated to the vapor source power with the deposition rate correlated to the measured flux rate.

18. The vapor deposition rate control system of claim 15, further comprising:
a vapor source temperature sensor capable of measuring a vapor source temperature of the vapor source; and
a first check control loop comprising a correlation function between flux rate and vapor source temperature to compare the flux rate correlated to the vapor source temperature with the measured flux rate.

19. The vapor deposition rate control system of claim 15, further comprising a data storage apparatus storing a target deposition layer thickness of a deposited vapor, wherein the data storage apparatus comprises a self-teaching algorithm to allow selection of the vapor flux rate as a function of the target deposition layer thickness.

20. The vapor deposition rate control system of claim 15, further comprising a film thickness monitor capable of measuring the thickness of a deposited vapor, wherein the film thickness monitor comprises an in-situ configuration when measuring the thickness of a deposited vapor.

21. The vapor deposition rate control system of claim 20, wherein the film thickness monitor comprises one or more of near infrared reflectometer, X-ray fluorescence sensor, ellipsometer, light scattering sensor, or optical transmission sensor.

22. The vapor deposition rate control system of claim 20, wherein the film thickness monitor can monitor the deposition process in real time.

23. The vapor deposition rate control system of claim 20, further comprising a film thickness control module capable of adjusting the vapor flux rate and iterating until the target deposition layer thickness is present.

24. The vapor deposition rate control system of claim 23, wherein the film thickness monitor measures deposition layer thickness after the flux rate is measured.

25. The vapor deposition rate control system of claim 22, wherein the vapor flux monitor comprises one or more of atomic absorption spectrometer, electron impact emission spectrometer, or ion gauge in a configuration enabling the monitor to measure the position sensitive flux rate.
